(19) United States
(12) Patent Application Publication
(10) Pub. No.: US 2024/0144986 A1
(43) Pub. Date: May 2, 2024

(54) MEMORY DEVICE

(71) Applicant: ROHM CO., LTD., Kyoto (JP)

(72) Inventors: Kazuma TAMURA, Kyoto (JP); Takeharu IMAI, Kyoto (JP)

(21) Appl. No.: 18/492,026

(22) Filed: Oct. 23, 2023

(30) Foreign Application Priority Data
Oct. 31, 2022 (JP) 2022-174102

(51) Int. Cl. G11C 7/10; G11C 29/52

(52) U.S. Cl. CPC G11C 7/1096; G11C 7/106; G11C 7/1069; G11C 29/52

(57) ABSTRACT

A memory device includes: a memory array configured such that memory cells are arranged in a form of a matrix in an X direction and a Y direction with the X direction being a direction in which a word line extends, and the Y direction being orthogonal to the X direction, wherein the memory array includes: first and second memory areas with first and second predetermined numbers of bits, respectively, which are arranged along the X direction in a same column extending in the Y direction; and a byte select transistor provided in common to select the first and second memory areas, wherein the first and second predetermined numbers of bits are equal, wherein the first and second memory areas have a same address, and wherein same bit data is written in paired memory cells in the first and second memory areas.

### CROSS-REFERENCE TO RELATED APPLICATION

This application is based upon and claims the benefit of priority from Japanese Patent Application No. 2022-174102, filed on Oct. 31, 2022, the entire contents of which are incorporated herein by reference.

### TECHNICAL FIELD

The present disclosure relates to a memory device.

### BACKGROUND

Memory devices including memory cells are known in the related art. The memory cells include memory transistors. In the related art, some memory transistors include, for example, a control gate and a floating gate and perform erasing/programming by injecting/extracting electrons to/from the floating gate by applying a high voltage to the control gate.

### BRIEF DESCRIPTION OF DRAWINGS

The accompanying drawings, which are incorporated in and constitute a part of the specification, illustrate embodiments of the present disclosure.

FIG. 1 is a schematic plan view showing a layout of each of a memory device according to a comparative example and a memory device according to an exemplary embodiment of the present disclosure.

FIG. 2 is a diagram showing an example of a memory address map in a memory device according to the present disclosure.

FIG. 3 is a schematic plan view showing configurations of latch circuits and bit lines in a Y decoder in the memory device according to the present disclosure.

FIG. 4 is a diagram showing a configuration related to data writing in the memory device according to the present disclosure.

FIG. 5 is a diagram showing a circuit configuration of a column latch.

FIG. 6 is a timing chart schematically showing waveforms of signals during data writing.

FIG. 7 is a diagram showing a configuration related to data reading in the memory device according to the present disclosure.

FIG. 8 is a diagram showing a functional truth table.

FIG. 9 is a diagram showing an exemplary operation in continuous read.

FIG. 10 is a schematic layout diagram showing a configuration of a memory device according to a comparative example.

FIG. 11 is a diagram showing a memory address map in the memory device according to the comparative example.

FIG. 12 is a schematic plan view showing a layout of first and second memory areas for one address.

FIG. 13 is a plan view schematically showing latch circuits and bit lines in a Y decoder in the memory device according to the comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, exemplary embodiments of the present disclosure will be described with reference to the drawings.

### <1. Challenges in Memory Device>

Here, prior to describing embodiments of the present disclosure, challenges in a memory device will be described.

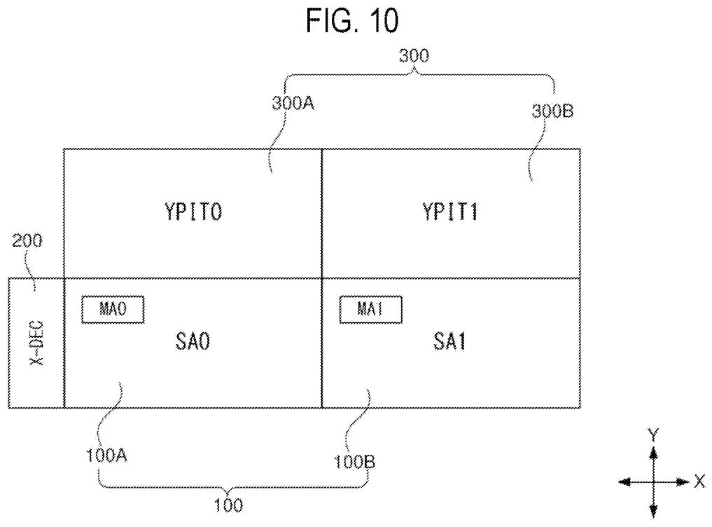

FIG. 10 is a schematic layout diagram showing a configuration of a memory device according to a comparative example. X and Y directions, which are orthogonal to each other, are shown in FIG. 10. FIG. 10 is a plan view seen from a direction perpendicular to the X direction and the Y direction. The memory device shown in FIG. 10 includes a memory array 100, an X decoder 200, and a Y decoder 300.

The memory array 100 is a nonvolatile memory and is configured as, for example, an EEPROM. The memory array 100 includes a first memory array 100A (SA0) and a second memory array 100B (SA1). The first memory array 100A and the second memory array 100B are arranged side by side in the X direction. Each of the first memory array 100A and the second memory array 100B is constituted by memory cells (not shown) arranged in the form of a matrix in the X direction and the Y direction. A memory cell may store 1 bit of data.

The first memory array 100A includes a first memory area MA0 constituted by memory cells for one address. The second memory array 100B includes a second memory area MA1 constituted by memory cells for one address. The first and second memory areas MA0 and MA1 are arranged in the form of a matrix in the first and second memory arrays 100A and 100B, respectively.

The first memory area MA0 and the second memory area MA1 are configured as a pair for the same address. Each of the first and second memory areas MA0 and MA1 is constituted by memory cells for a predetermined number of bits arranged in the X direction. Herein, for example, each of the first and second memory areas MA0 and MA1 is constituted by memory cells for 8 bits (that is, 8 memory cells). Further, each of the first and second memory areas MA0 and MA1 is provided with a byte select transistor configured to select memory cells for a predetermined number of bits.

A 1-bit memory cell in the first memory area MA0 and a 1-bit memory cell in the second memory array MA1 are configured as a pair, and are written (data write) and read (data read) at the same time. The same data (0 or 1) is written into the paired memory cells. Therefore, even in a case where data corruption (1→0) occurs accidentally in one memory cell, the data may be corrected by inputting the read data to an OR circuit. Reliability of the memory cells is improved by adopting a double cell method in which such two memory cells substantially store one bit of data.

The X decoder 200 and the Y decoder 300 are cell peripheral circuits arranged around the memory array 100. The Y decoder 300 includes a first Y decoder 300A (YPIT0) provided corresponding to the first memory array 100A, and a second Y decoder 300B (YPIT1) provided corresponding to the second memory array 100B. The first and second Y decoders 300A and 300B are arranged side by side in the X direction and are arranged side by side in the Y direction with the first and second memory arrays 100A and 100B, respectively.

Word lines (not shown), which are address select lines drawn out from the X decoder 200 and extending in the X direction, traverses the memory array 100 in the X direction. Bit lines (not shown), which are address select lines drawn out from the first and second Y decoders 300A and 300B and extending in the Y direction, traverse the memory array 100 in the Y direction.

The X decoder 200 decodes an address signal in the X direction and selects a word line. The Y decoder 300 decodes an address signal in the Y direction and selects a bit line. The first memory area MA0 is selected by the X decoder 200 and the first Y decoder 300A, and the second memory area MA1 is selected by the X decoder 200 and the second Y decoder 300B. The paired first memory area MA0 and second memory area MA1 are selected simultaneously to perform writing and reading.

When reading data, the data is read from a selected memory cell by using a sense amplifier. Sense amplifiers are arranged in a sense amplifier area (not shown) and are provided in the same number as the number of bits of memory cells in the first and second memory areas MA0 and MA1 (that is, 8 sense amplifiers are provided for 8 bits).

Further, when writing data, writing (write process) is performed by applying a high voltage to a selected memory cell. The high voltage is applied by a charge pump (not shown).

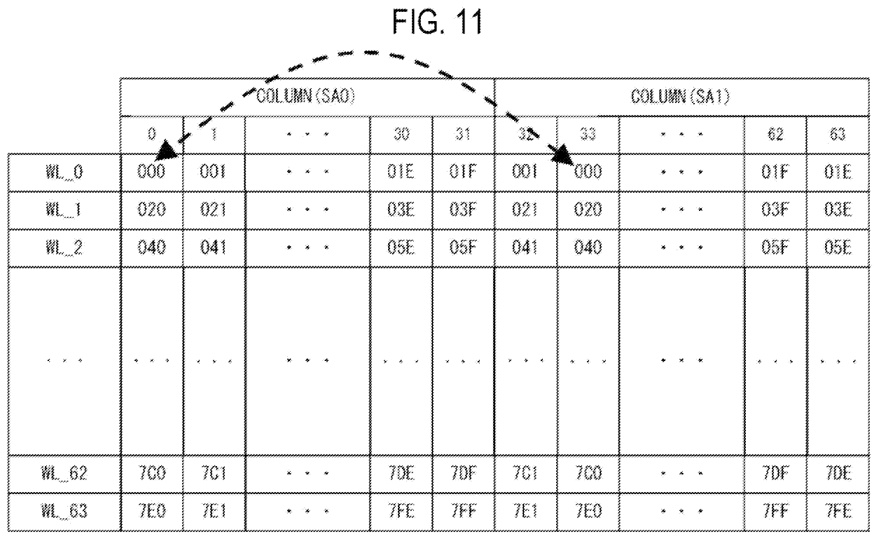

FIG. 11 is a diagram showing a memory address map in the memory device according to the comparative example. As shown in FIG. 11, in the first memory array 100A (SA0), the first memory areas MA0 for one address are arranged in the form of a matrix by the number of word lines (WL_0 to WL_63) in the Y direction and the number of columns (0 to 31) in the X direction. A column is an area for one line extending in the Y direction. Similarly, in the second memory array 100B (SA1), the second memory areas MA1 for one address are arranged in the form of a matrix by the number of word lines (WL_0 to WL_63) in the Y direction and the number of columns (32 to 63) in the X direction. Therefore, in the example of FIG. 11, data capacity of each of the first and second memory arrays 100A and 100B is 8 bits×64×32=16 Kbits. As described above, the first and second memory areas MA0 and MA1 at the same address (for example, 000 in FIG. 11) are configured as a pair and are accessed simultaneously for writing and reading.

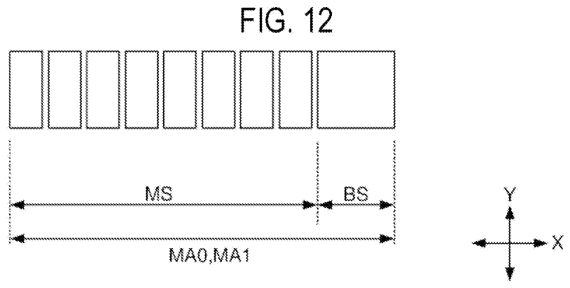

FIG. 12 is a schematic plan view showing a layout of the first and second memory areas MA0 and MA1 for one address. As shown in FIG. 12, the first and second memory areas MA0 and MA1 for one address include a cell area MS in which memory cells for a predetermined number of bits (8 bits in FIG. 12) are arranged, and a byte select transistor BS. In the first and second memory areas MA0 and MA1 for one address, a proportion occupied by the byte select transistor BS is relatively large, for example, 30%. The double cell method requires twice as many byte select transistors BS as a single cell method, which increases an area of the memory array 100.

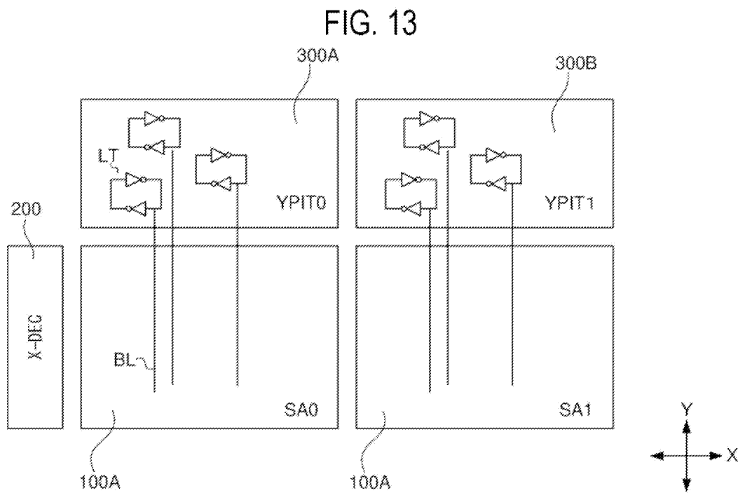

FIG. 13 is a plan view schematically showing latch circuits and bit lines in the Y decoder in the memory device according to the comparative example. For one column, bit lines BL extending in the Y direction are provided in the number corresponding to a predetermined number of bits (for example, eight bit lines for 8 bits) in the first and second memory areas MA0 and MA1. In the example of FIG. 11, since there are 32 columns in each of the first and second memory arrays 100A and 100B, 8×32=256 bit lines BL are provided in each of the first and second memory arrays 100A and 100B.

Further, as shown in FIG. 13, a latch circuit LT is formed for each bit line BL in the first and second Y decoders 300A and 300B. The latch circuit LT is a circuit configured to latch write data for writing. That is, the same number of latch circuits LT as the number of bit lines BL are provided. In the example of FIG. 11, 256 latch circuits LT are provided in each of the first and second Y decoders 300A and 300B. The number of latch circuits LT is the number of page buffers including the latch circuits LT. This requires twice as many page buffers as in the single cell method, which increases an area of the Y decoder 300.

### <2. Improvement of Memory Array>

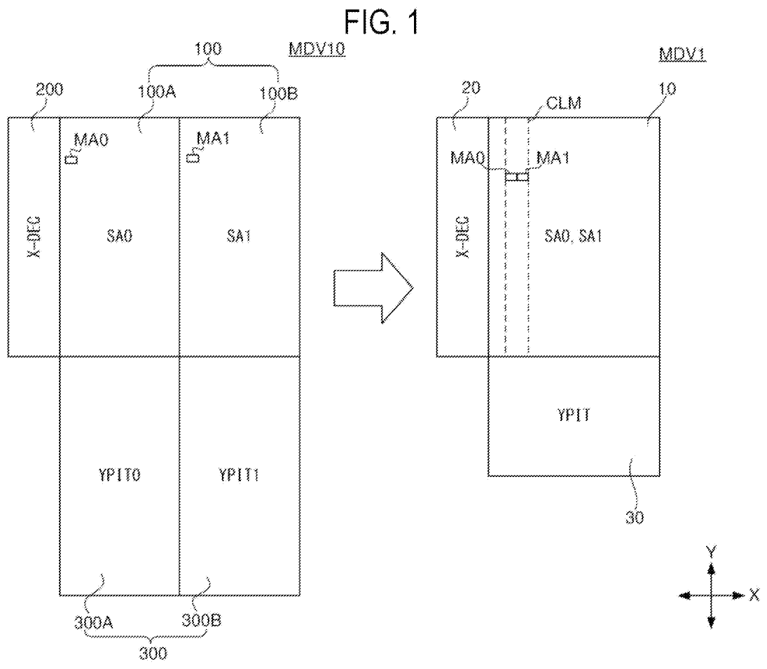

In view of the challenges in the comparative example as described above, embodiments of the present disclosure described below are implemented. FIG. 1 is a schematic plan view showing layouts of each of a memory device MDV10 according to a comparative example and a memory device MDV1 according to an exemplary embodiment of the present disclosure.

Although the memory device MDV10 shown in FIG. 1 is different from the memory device according to the comparative example shown in FIG. 10 in the number of columns and the number of word lines, the memory device MDV10 is constituted by using a double cell method with a similar design concept. That is, in the memory device MDV10, the first and second memory areas MA0 and MA1 paired at the same address are provided in the first and second memory arrays 100A and 100B which are areas separated in the X direction, respectively.

In contrast, the memory device MDV1 according to the present disclosure includes a memory array 10, an X decoder 20, and a Y decoder 30. In the memory array 10, first and second memory areas MA0 and MA1 paired at the same address in the same column CLM are arranged adjacent to each other in the X direction. As a result, in the memory device MDV10, a byte select transistor is required for each of the paired first and second memory areas MA0 and MA1, but in the memory device MDV1, only one byte select transistor is required for the paired first and second memory areas MA0 and MA1. Therefore, in the memory device MDV1, since the number of byte select transistors may be reduced, an area of the memory array 10 may be reduced by that amount. For example, the area of the memory array 10 may be reduced by 20% compared to the area of the memory array 100. Therefore, the actual area of the memory array may be reduced while employing the double cell method.

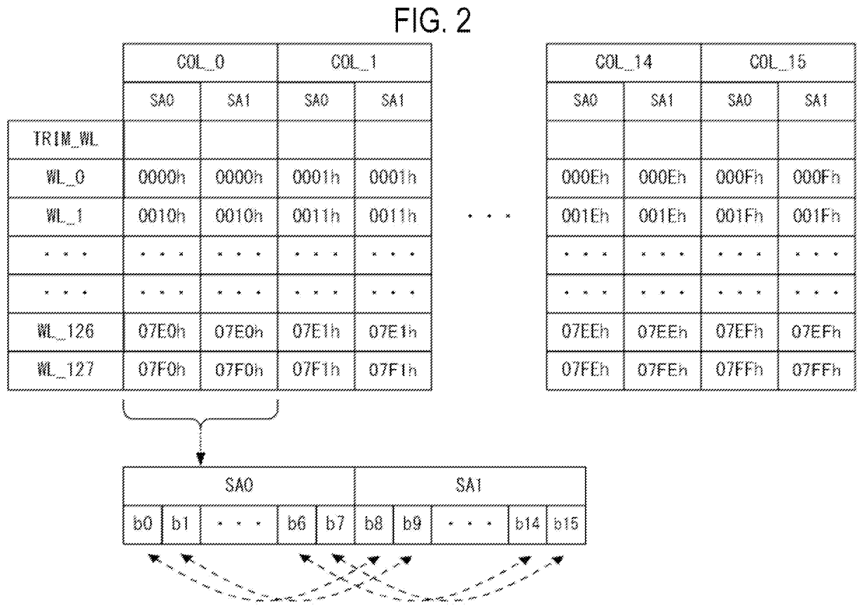

FIG. 2 is a diagram showing an example of a memory address map in the memory device MDV1 according to the present disclosure. As shown in FIG. 2, the first memory area MA0 (SA0) and second memory area MA1 (SA1) paired at the same address in the same column (COL_0 to COL_15) are arranged adjacent to each other in the X direction. For example, the first and second memory areas MA0 and MA1 at the same address 0000h are arranged in the column COL_0. Further, the paired first and second memory areas MA0 and MA1 are arranged in the Y direction by the number of word lines (WL_0 to WL_127).

As shown in the lower part of FIG. 2, memory cells of a predetermined number of bits (herein, 8 bits) are arranged in each of the paired first and second memory areas MA0 and MA1. In the example of FIG. 2, since the predetermined number of bits=8 bits, the number of columns=16, and the number of word lines=128, data capacity of the memory array 10 is 8 bits×2×16×128=32 Kbits. However, since the double cell method is adopted, the actual data capacity is 16 Kbits.

As shown in FIG. 2, the memory cells of each of bits b0 to b7 in the first memory area MA0 (SA0) are paired one-to-one with the memory cell of each of bits b8 to b15 in the second memory area MA1 (SA1). In FIG. 2, since the memory cells of bits b1 to b7 are arranged between the memory cells of the paired bits b0 and b8, the memory cells of the paired bits b0 and b8 are not adjacent to each other in the X direction. Similarly, the paired bits b1 and b9 to the paired b7 and b15 are not adjacent to each other in the X direction. This makes it possible to suppress simultaneous data corruption (1→0) due to interference between memory cells. Since data cannot be corrected by an OR circuit in the case where the simultaneous data corruption occurs, it is desirable to avoid the simultaneous data corruption. In the configuration shown in FIG. 2, all the memory cells (b0 to b7) in the first memory area MA0 are sequentially adjacent to each other in the X direction, and all the memory cells (b8 to b15) in the second memory area MA1 are sequentially adjacent to each other in the X direction. According to such a configuration, it is possible to space apart the paired memory cells from each other as far apart as possible.

Without being limited to the example shown in FIG. 2, a partial area of the first memory area MA0 and a partial area of the second memory area MA1 may be alternately arranged in the X direction, such as arranging b8 and b9 adjacent to b0 and b1 and arranging b2 and b3 adjacent to b8 and b9. This also prevents the paired memory cells from being adjacent to each other in the X direction. Further, the present embodiment does not exclude a configuration in which the paired memory cells are adjacent to each other in the X direction.

In FIG. 2, an area for 16 columns corresponding to a word line TRIM_WL is a special memory area different from normally used areas (WL_0 to WL_127). This memory area stores, for example, device-specific data (manufacturer code, etc.), trimming data for analog value correction, shipping history information, and the like.

### <3. Improvement of Y Decoder>

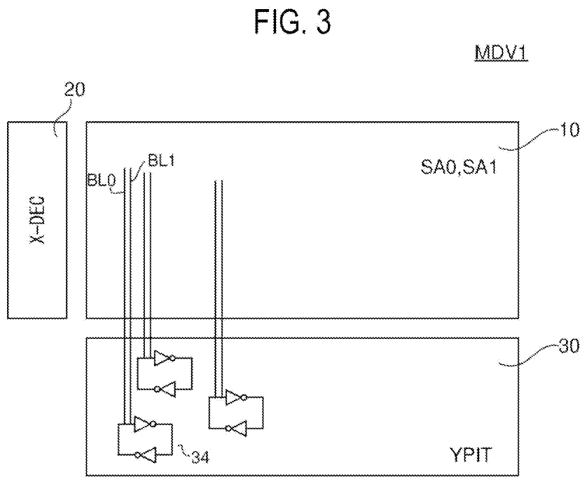

FIG. 3 is a schematic plan view showing configurations of latch circuits 34 and bit lines BL0 and BL1 in the Y decoder 30 in the memory device MDV1 according to the present disclosure.

As shown in FIG. 3, in the present embodiment, the first and second bit lines BL0 and BL1 respectively connected to the paired memory cells in the first and second memory areas MA0 and MA1 are connected to one common latch circuit 34. Therefore, a page buffer including the latch circuit is required for each of the paired memory cells in the comparative example, but one page buffer is shared in the present embodiment, such that the area of the Y decoder 30 may be reduced.

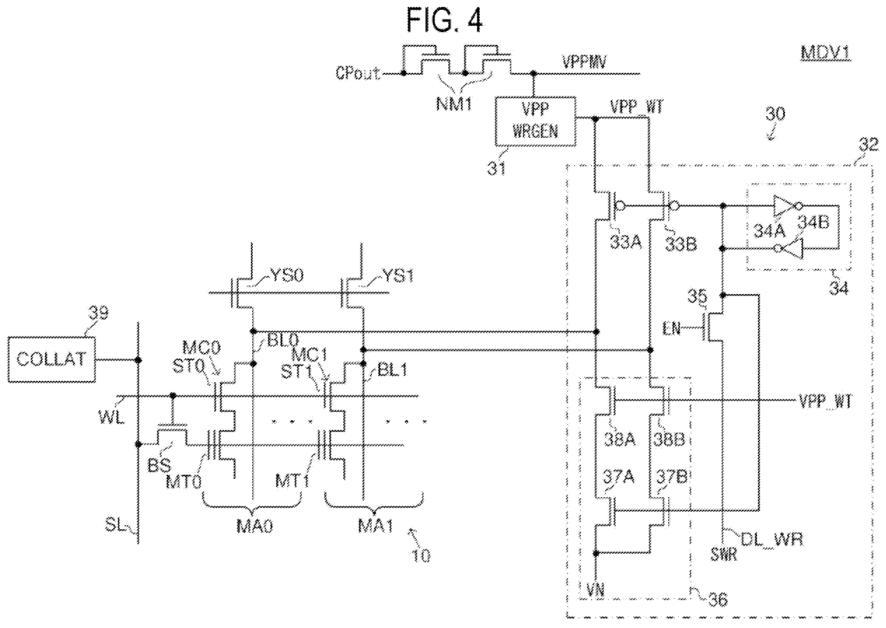

FIG. 4 is a diagram showing a configuration related to data writing in the memory device MDV1 according to the present disclosure. FIG. 4 also shows a partial configuration of the memory array 10. The memory array 10 includes the paired first and second memory areas MA0 and MA1. The first memory area MA0 includes memory cells MC0 of a predetermined number of bits (for example, 8 bits). Each memory cell MC0 includes a select transistor ST0 and a memory transistor MT0.

The memory transistor MT0 includes a control gate and a floating gate. A first end of the select transistor ST0 is connected to the bit line BL0. A second end of the select transistor ST0 is connected to a first end of the memory transistor MT0. The same number of memory cells MC0 as the number of word lines WL is connected to one bit line BL0.

The second memory area MA1 includes memory cells MC1 of a predetermined number of bits (for example, 8 bits). Each memory cell MC1 includes a select transistor ST1 and a memory transistor MT1.

The memory transistor MT1 includes a control gate and a floating gate. A first end of the select transistor ST1 is connected to the bit line BL1. A second end of the select transistor ST1 is connected to a first end of the memory transistor MT1. The same number of memory cells MC1 as the number of word lines WL is connected to one bit line BL1.

One word line WL is connected to a control end (read gate) of each of the select transistors ST0 and ST1 arranged in the X direction.

The memory array 10 is provided with a byte select transistor BS. The byte select transistor BS is provided for each pair of the first and second memory areas MA0 and MA1. A select line SL extending in the Y direction traverses the memory array 10. One select line SL is connected to a first end of each of the byte select transistors BS arranged in the Y direction. A second end of one byte select transistor BS is connected to a control gate of each of the memory transistors MT0 and MT1 included in the paired first and second memory areas MA0 and MA1. That is, in a case where the predetermined number of bits is 8 bits, one byte select transistor BS is connected to 16 (=8+8) memory transistors. A control end of the byte select transistor BS is connected to the word line WL.

Erase processing and write processing may be performed on the memory cells MC0 and MC1. During the erase processing, a high voltage (for example, 17 V) is applied to a selected word line WL, thereby turning on the corresponding select transistors ST0 and ST1. Further, the byte select transistor BS corresponding to the selected word line WL is turned on, and a high voltage (for example, 17 V) is applied to the control gates of the corresponding memory transistors MT0 and MT1 via the select line SL. Further, 0 V is applied to the first ends of the corresponding memory transistors MT0 and MT1 via the selected bit lines BL0 and BL1. As a result, electrons are injected into the floating gates of the memory transistors MT0 and MT1, resulting in a state in which data “1” is written.

On the other hand, during the write processing, a high voltage (for example, 17 V) is applied to the selected word line WL, thereby turning on the corresponding select transistors ST0 and ST1. Further, the byte select transistor BS corresponding to the selected word line WL is turned on, and 0 V is applied to the control gates of the corresponding memory transistors MT0 and MT1 via the select line SL. Further, a high voltage (for example, 14 V) is applied to the first ends of the corresponding memory transistors MT0 and MT1 via the selected bit lines BL0 and BL1. As a result, electrons are extracted from the floating gates of the memory transistors MT0 and MT1, resulting in a state in which data “0” is written. A charge pump (not shown in FIG. 4) is used to apply the high voltage to the memory transistors MT0 and MT1 via the bit lines BL0 and BL1.

Control of applying a voltage to the control gates of the memory transistors MT0 and MT1 via the byte select transistor BS is performed by a column latch 39 connected to the select line SL. The column latch 39 is provided in the Y decoder 30.

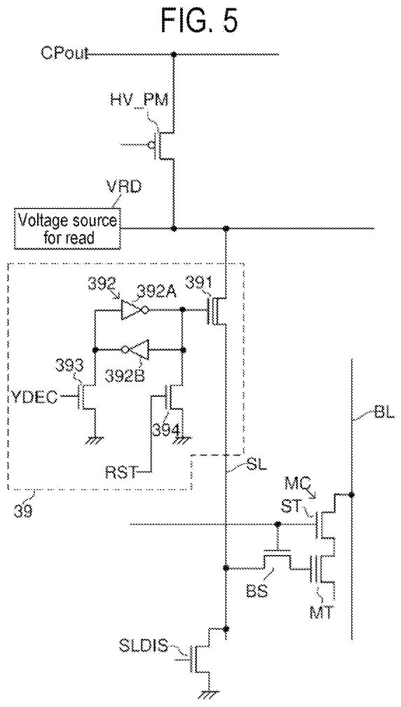

FIG. 5 shows a circuit configuration of the column latch 39. The column latch 39 includes a depression type NMOS transistor 391, a latch 392, and switches 393 and 394. A drain of the NMOS transistor 391 is connected to a drain of a PMOS transistor HV_PM. A source of the PMOS transistor HV_PM is connected to an application end of a charge pump output voltage CPout output from a charge pump (not shown). Further, the drain of the NMOS transistor 391 is connected to an output end of a voltage source VRD for read. The latch 392 includes inverters 392A and 392B. An output end of the inverter 392A is connected to a gate of the NMOS transistor 391. An input end of the inverter 392B is connected to the output end of the inverter 392A. An output end of the inverter 392B is connected to an input end of the inverter 392A. A first end of the switch 393 is connected to the output end of the inverter 392B. A second end of the switch 393 is connected to an application end of the ground potential. A first end of the switch 394 is connected to the gate of the NMOS transistor 391. A second end of the switch 394 is connected to an application end of the ground potential. The switch 393 is controlled to be turned on/off by a Y-line select signal YDEC. The switch 394 is controlled to be turned on/off by a reset signal RST.

Herein, an operation of the column latch 39 when reading data will be described. When reading data, the switch 393 is turned on and the switch 394 is turned off, such that the output of the latch 392 (gate voltage of the NMOS transistor 391) is set to a high level and the NMOS transistor 391 is turned on. At this time, the PMOS transistor HV_PM is in a turn-off state, and a predetermined voltage for reading (for example, 1.4 V) is output from the voltage source VRD for read. As a result, the predetermined voltage is applied to the select line SL. That is, a column may be selected by applying the predetermined voltage for reading (for example, 1.4 V) to the select line SL by the column latch 39. The operation of the column latch 39 when writing data will be described later.

Next, returning to FIG. 4, a configuration regarding the data writing in the memory device MDV1 will be described. In the memory device MDV1, the Y decoder 30 includes a page buffer 32. The page buffer 32 includes a data latch circuit 34, a PMOS transistor 33A, a PMOS transistor 33B, and an NMOS transistor 35.

One end of a write data line DL_WR is connected to a first end of the NMOS transistor 35. A second end of the NMOS transistor 35 is connected to the data latch circuit 34. The data latch circuit 34 includes inverters 34A and 34B. An input end of the inverter 34A and an output end of inverter 34B are connected to each other, and an output end of the inverter 34A and an input end of the inverter 34B are connected to each other.

The NMOS transistor 35 is controlled to be turned on/off by a write data set enable signal EN. When the write data set enable signal EN is at a high level, the NMOS transistor 35 is turned on. At this time, since a write data signal SWR input to the write data line DL_WR is applied to the data latch circuit 34, data is set by the write data signal SWR. Even when the NMOS transistor 35 is turned off, the data is latched by the data latch circuit 34.

The data latch circuit 34 is connected to the gate of each of the PMOS transistors 33A and 33B. When data of low level is latched, the PMOS transistors 33A and 33B are turned on. On the other hand, when data of high level is latched, the PMOS transistors 33A and 33B are turned off.

A high-voltage pulse generator 31 is provided in the memory device MDV1. The high-voltage pulse generator 31 is a circuit configured to output a high-voltage pulse during write processing which will be described later. An output end of the high-voltage pulse generator 31 is connected to first ends of the PMOS transistors 33A and 33B. Second ends of the PMOS transistors 33A and 33B are connected to the bit lines BL0 and BL1, respectively.

The charge pump output voltage CPout output from the charge pump (not shown) is stepped down by a two-stage NMOS transistor NM1 to a step-down voltage VPPMV. The step-down voltage VPPMV is supplied to the high-voltage pulse generator 31.

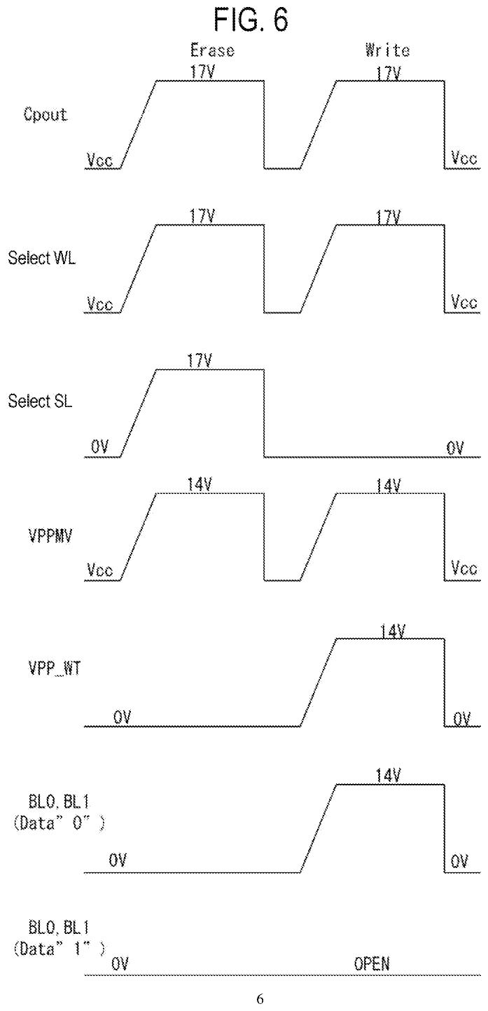

FIG. 6 is a timing chart schematically showing waveforms of signals during the data writing. FIG. 6 shows, sequentially from the top, a charge pump output voltage CPout, a voltage of a selected word line WL, a voltage of a selected select line SL, a step-down voltage VPPMV, and a high-voltage output voltage VPP_WT output from the high-voltage pulse generator 31, a voltage of the bit lines BL0 and BL1 when writing data “0” in a memory cell, and a voltage of the bit lines BL0 and BL1 when writing data “1” in the memory cell. In FIG. 6, as an example, a high voltage generated by a charge pump is set to be 17 V.

When writing data, erase processing and write processing are performed successively. In the erase processing, the charge pump output voltage CPout rises from a power supply voltage Vcc to 17 V. At this time, the step-down voltage VPPMV is stepped down from 17 V by, for example, 3 V to 14 V by the two-stage NMOS transistor NM1. The high-voltage pulse generator 31 outputs high-voltage output voltages VPP_WT_A and VPP_WT_B of 0 V.

At this time, since data of low level is latched by the data latch circuit 34, the PMOS transistors 33A and 33B are turned on, and 0 V is applied to the bit lines BL0 and BL1. At this time, in the column latch 39 (FIG. 5), since the NMOS transistor 391 is turned on and the PMOS transistor HV_PM is turned on, 17 V is applied to the selected select line SL. As a result, the select transistors ST0 and ST1 are turned on in the memory cells MC0 and MC1 to be written, and a high voltage (17 V in this case) is applied to the control gates of the memory transistors MT0 and MT1. Therefore, electrons are injected into the floating gates of the memory transistors MT0 and MT1 in the memory cells MC0 and MC1 to be written, and the memory transistors MT0 and MT1 are placed in an erased state.

After the erase processing, in the write processing, the charge pump output voltage CPout rises again from the power supply voltage Vcc to 17 V. At this time, the step-down voltage VPPMV becomes 14 V. The high-voltage pulse generator 31 outputs a high-voltage output voltage VPP_WT of 14 V. That is, a high-voltage pulse is generated during the write processing.

At this time, when writing data “0” in a memory cell to be written, since the data of low level is latched by the data latch circuit 34, the PMOS transistors 33A and 33B are turned on, and 14 V is applied to the bit lines BL0 and BL1. At this time, a switch SLDIS (FIG. 5) configured to set the select line SL to a ground potential is connected to the select line SL. When the switch SLDIS is turned on (both the NMOS transistor 391 and the PMOS transistor HV_PM are turned off), 0 V is applied to the selected select line SL. As a result, the select transistors ST0 and ST1 are turned on in the memory cells MC0 and MC1 to be written, and 0 V is applied to the control gates of the memory transistors MT0 and MT1. Therefore, electrons are extracted from the floating gates of the memory transistors MT0 and MT1 in the memory cells MC0 and MC1 to be written, and the memory transistors MT0 and MT1 are brought into the write state (“0”).

On the other hand, when writing data “1” in the memory cell to be written, since the data of high level is latched by the data latch circuit 34, the PMOS transistors 33A and 33B are turned off, and the bit lines BL0 and BL1 are opened. Therefore, electrons are not extracted from the floating gates of the memory transistors MT0 and MT1 in the memory cells MC0 and MC1 to be written, and the memory transistors MT0 and MT1 are maintained in the erased state (“1”).

Further, in the memory device MDV1, the Y decoder 30 includes a clamp circuit 36. The clamp circuit 36 includes NMOS transistors 37A and 37B and NMOS transistors 38A and 38B. A clamping voltage VN is applied to a first end of the NMOS transistor 37A. The data latch circuit 34 is connected to the gate of the NMOS transistor 37A. A second end of the NMOS transistor 37A is connected to a first end of the NMOS transistor 38A. A second end of the NMOS transistor 38A is connected to the second end of the PMOS transistor 33A. The clamping voltage VN is applied to a first end of the NMOS transistor 37B. The data latch circuit 34 is connected to the gate of the NMOS transistor 37B. A second end of the NMOS transistor 37B is connected to a first end of the NMOS transistor 38B. A second end of the NMOS transistor 38B is connected to the second end of the PMOS transistor 33B.

When writing data “1” in the memory cell to be written, the data of high level is latched by the data latch circuit 34 during the write processing, and the PMOS transistors 33A and 33B are turned off. At this time, the NMOS transistors 37A and 37B are turned on, and when the high-voltage output voltage VPP_WT becomes a high voltage (14 V), the NMOS transistors 38A and 38B are turned on, and the clamping voltage VN is applied to the bit lines BL0 and BL1. As a result, when a high voltage is applied to a bit line adjacent to the bit lines BL0 and BL1, the voltage of the bit lines BL0 and BL1 may be clamped to be equal to or less than the clamping voltage VN, and a voltage increase of the bit lines BL0 and BL1 may be suppressed.

As described above, in the present embodiment, the PMOS transistors 33A and 33B configured to output the high-voltage output voltage VPP_WT are provided to correspond to the bit lines BL0 and BL1 and to divide the output into two systems. As a result, in the memory device MDV10 according to the comparative example, a page buffer of a one-system output is provided for each of the memory cells MC0 and MC1, but in the present embodiment, one page buffer 32 may be shared, such that the area of the Y decoder 30 may be reduced. In FIG. 1, the area of the Y decoder 30 is approximately half the area of the Y decoder 300 in the comparative example.

### <4. Configuration of Read Processing>

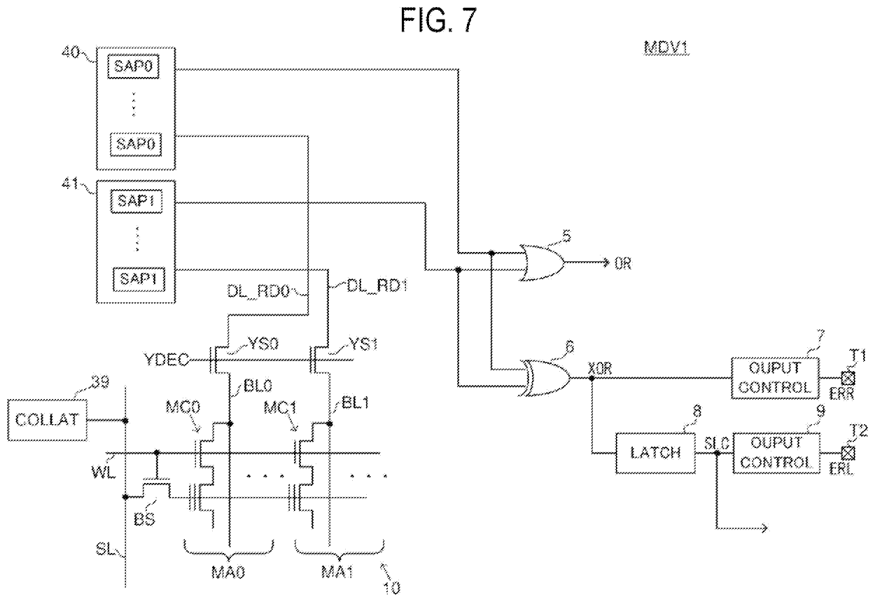

FIG. 7 is a diagram showing a configuration related to data reading in the memory device MDV1 according to the present disclosure. Since the configuration of the memory array 10 and the column latch 39 in FIG. 7 are the same as those in FIG. 4 described above, detailed explanation thereof will be omitted.

The memory device MDV1 according to the present embodiment is provided with a first sense amplifier area 40 configured to read data from the first memory area MA0 and a second sense amplifier area 41 configured to read data from the second memory area MA1. The sense amplifier detects that “1” is written in a memory transistor when no current flows through a memory cell, and detects that “0” is written in the memory transistor when a current flows through the memory cell.

The first sense amplifier area 40 is provided with a number of sense amplifiers SAP0 corresponding to a predetermined number of bits of the memory cells MC0 in the first memory area MA0, and the second sense amplifier area 41 is provided with a number of sense amplifiers SAP1 corresponding to a predetermined number of bits of the memory cells MC1 in the second memory area MA1. When the predetermined number of bits is 8 bits, eight sense amplifiers SAP0 and SAP1 are respectively provided.

Each bit line BL0 connected to each memory cell MC0 in the first memory area MA0 is connected to each sense amplifier SAP0 in the first sense amplifier area 40 via each Y line select switch YS0 and each read data line DL_RD0. Each bit line BL1 connected to each memory cell MC1 in the second memory area MA1 is connected to each sense amplifier SAP1 in the second sense amplifier area 41 via each Y line select switch YS1 and each read data line DL_RD1. The Y line select switches YS0 and YS1 are controlled to be turned on/off by the Y-line select signal YDEC.

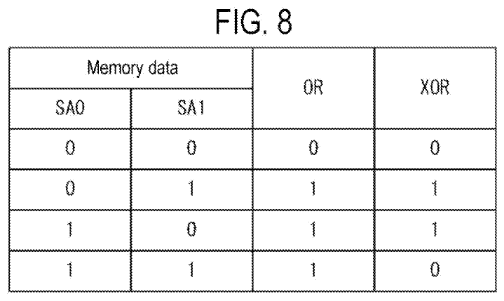

An output end of each of the sense amplifiers SAP0 and SAP1 corresponding to the paired memory cells MC0 and MC1 is connected to an input end of each of OR circuits 5. The OR circuits 5 are provided in a number (for example, eight) corresponding to the predetermined number of bits. Herein, a truth table shown in FIG. 8 shows a relationship between the data (SA0 and SA1) written in the paired memory cells MC0 and MC1 and an output OR of the OR circuit 5. As shown in the truth table, when the data written in the memory cells MC0 and MC1 are both 0, the output OR becomes 0, and when the data are both 1, the output OR becomes 1. In a case where data corruption (1→0) occurs accidentally in one of the data written in the memory cells MC0 and MC1, the output OR becomes 1 and the data may be corrected. In this way, reliability of the memory cells is improved by the double cell method.

Further, the output end of each of the sense amplifiers SAP0 and SAP1 corresponding to the paired memory cells MC0 and MC1 is also connected to an input end of each of XOR circuits 6. The XOR circuits 6 are provided in a number (for example, eight) corresponding to the predetermined number of bits. The truth table shown in FIG. 8 shows a relationship between the data (SA0 and SA1) written in the paired memory cells MC0 and MC1 and an output XOR of the XOR circuit 6. As shown in the truth table, when the data written in the memory cells MC0 and MC1 both match as 0 or 1, the output XOR becomes 0. On the other hand, in a case where data corruption occurs in one of the data written in the memory cells MC0 and MC1 and the data do not match, the output XOR becomes 1. Therefore, in the double cell method, it is possible to perform not only correction of the data but also detection of data corruption. This eliminates a need to test by performing writing and reading for each of the memory cells MC0 and MC1, thereby shortening a test time.

The output of the XOR circuit 6 may be output as an error signal ERR from an external terminal T1 via an output control circuit 7. A logic level of the output of the XOR circuit 6 is reflected, as it is, in a logic level of the error signal ERR. This makes it possible to notify external parts of data corruption errors.

Further, the output of the XOR circuit 6 is input to a latch circuit 8. The latch circuit 8 outputs a latch signal SLC latched from low level to high level, for example, when the output of the XOR circuit 6 changes from 0 to 1, that is, when an error is detected. After the latch, the level of the latch signal SLC is maintained regardless of the output of the XOR circuit 6. The output of the latch circuit 8 is outputted as an error detection latch signal ERL from an external terminal T2 via an output control circuit 9. The latch of the latch signal SLC is reflected in the latch of the error detection latch signal ERL.

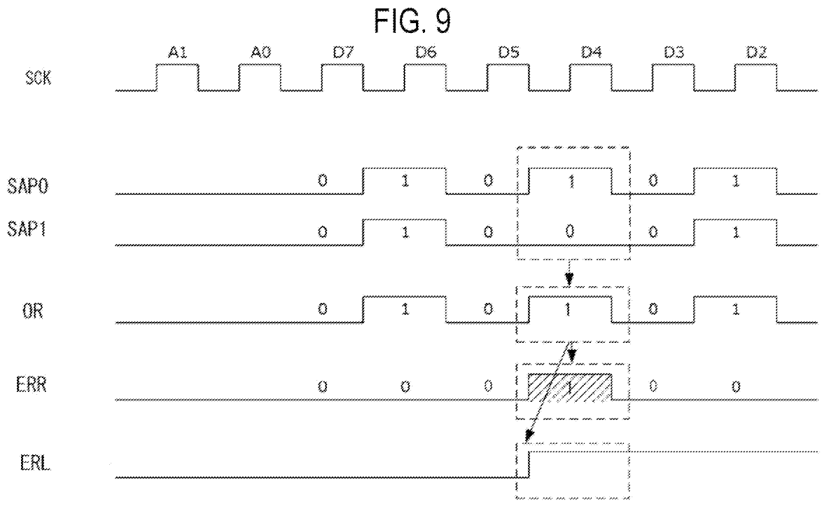

FIG. 9 shows an exemplary operation in continuous read in which data is read while changing an address every clock. FIG. 9 shows, sequentially from the top, a clock signal SCK, the outputs of the sense amplifiers SAP0 and SAP1, the output of the OR circuit 5, the error signal ERR, and the error detection latch signal ERL.

As shown by broken line frames in FIG. 9, when a mismatch occurs between the data read by the sense amplifiers SAP0 and SAP1, the output of the OR circuit 5 becomes 1 and the data is corrected. On the other hand, the output of the XOR circuit 6 becomes 1, the error signal ERR becomes 1, and the data corruption is detected as an error. At this time, since the latch signal SLC changes from low level to high level and is latched, the error detection latch signal ERL also changes from low level to high level and is latched. This improves traceability.

Further, when the latch signal SLC is latched, data indicating that an abnormality has occurred is written in the special memory area (TRIM_WL) shown in FIG. 2 in the memory array 10. This also improves traceability.

### <5. Others>

Various technical features of the present disclosure may be modified in addition to the above-described embodiments without departing from the spirit of the technical creation. That is, the above-described embodiments should be considered to be illustrative in all respects and not restrictive, and the technical scope of the present disclosure is not limited to the above-described embodiments. It should be understood that all changes that come within the meaning and range of equivalents of the claims are included in the technical scope of the present disclosure.

### <6. Supplementary Notes>

As described above, for example, a memory device (MDV1) according to the present disclosure is configured to include: a memory array (10) configured such that memory cells (MC0, MC1) are arranged in a form of a matrix in an X direction and a Y direction with the X direction being a direction in which a word line (WL) extends, and the Y direction being orthogonal to the X direction,
wherein the memory array includes:
a first memory area (MA0) with a first predetermined number of bits and a second memory area (MA1) with a second predetermined number of bits, which are arranged along the X direction in a same column (CLM) extending in the Y direction; and
a byte select transistor (BS) provided in common to select the first memory area and the second memory area,
wherein the first predetermined number of bits and the second predetermined number of bits are equal,
wherein the first memory area and the second memory area have a same address, and
wherein same bit data is written in paired memory cells (MC0, MC1) in the first memory area and the second memory area (first configuration).

In the memory device of the first configuration, other memory cells may be arranged between the paired memory cells in the X direction (second configuration).

In the memory device of the second configuration, all memory cells in the first memory area (MA0) may be sequentially adjacent to each other in the X direction, and all memory cells in the second memory area (MA1) may be sequentially adjacent to each other in the X direction (third configuration).

In the memory device of any one of the first to third configurations, the memory device may further include a page buffer (32),
wherein the page buffer (32) may include:
a latch circuit (34) configured to latch write data; and
a first control transistor and a second control transistor (33A, 33B), each including a control end connected to the latch circuit and a first end configured to be capable of being supplied with a high voltage, and
wherein a first bit line and a second bit line (BL0, BL1) respectively connected to the paired memory cells may be respectively connected to second ends of the first control transistor and the second control transistor (fourth configuration).

In the memory device of any one of the first to fourth configurations, the memory device may further include:
a first reader and a second reader (SAP0, SAP1) configured to read data from each of the paired memory cells; and
an OR circuit (5) configured to be supplied with an output of each of the first reader and the second reader (fifth configuration).

In the memory device of the fifth configuration, the memory device may further include an XOR circuit (6) configured to be supplied with an output of each of the first reader and the second reader (sixth configuration).

In the memory device of the sixth configuration, the memory device may further include a first external terminal (T1) configured to externally output an error signal (ERR) based on an output of the XOR circuit, wherein a logic level of the output of the XOR circuit may be reflected, as it is, in a logic level of the error signal (seventh configuration).

In the memory device of the sixth configuration, continuous read may be performed by changing an address every clock to perform read processing, and
the memory device may further include a latch circuit (8) configured to output a latch signal (SLC) latched by changing a level when the output of the XOR circuit changes from 0 to 1 (eighth configuration).

In the memory device of the eighth configuration, the memory device may further include a second external terminal (T2) configured to externally output an error detection latch signal (ERL) based on the latch signal, and
the latch of the latch signal may be reflected in latch of the error detection latch signal (ninth configuration).

In the memory device of the eighth configuration, when the latch signal is latched, data indicating an abnormality may be written in the memory array (tenth configuration).

### INDUSTRIAL APPLICABILITY

The present disclosure may be used in memory devices for various uses.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A memory device comprising:
a memory array configured such that memory cells are arranged in a form of a matrix in an X direction and a Y direction with the X direction being a direction in which a word line extends, and the Y direction being orthogonal to the X direction,
wherein the memory array includes:
a first memory area with a first predetermined number of bits and a second memory area with a second predetermined number of bits, which are arranged along the X direction in a same column extending in the Y direction; and
a byte select transistor provided in common to select the first memory area and the second memory area,
wherein the first predetermined number of bits and the second predetermined number of bits are equal,
wherein the first memory area and the second memory area have a same address, and
wherein same bit data is written in paired memory cells in the first memory area and the second memory area.

2. The memory device of claim 1, wherein other memory cells are arranged between the paired memory cells in the X direction.

3. The memory device of claim 2, wherein all memory cells in the first memory area are sequentially adjacent to each other in the X direction, and all memory cells in the second memory area are sequentially adjacent to each other in the X direction.

4. The memory device of claim 1, further comprising a page buffer,
wherein the page buffer includes:
a latch circuit configured to latch write data; and
a first control transistor and a second control transistor, each including a control end connected to the latch circuit and a first end configured to be capable of being supplied with a high voltage, and
wherein a first bit line and a second bit line respectively connected to the paired memory cells are respectively connected to second ends of the first control transistor and the second control transistor.

5. The memory device of claim 1, further comprising:
a first reader and a second reader configured to read data from each of the paired memory cells; and
an OR circuit configured to be supplied with an output of each of the first reader and the second reader.

6. The memory device of claim 5, further comprising an XOR circuit configured to be supplied with the output of each of the first reader and the second reader.

7. The memory device of claim 6, further comprising a first external terminal configured to externally output an error signal based on an output of the XOR circuit,
wherein a logic level of the output of the XOR circuit is reflected, as it is, in a logic level of the error signal.

8. The memory device of claim 6, wherein continuous read is performed by changing an address every clock to perform read processing, and
wherein the memory device further comprises a latch circuit configured to output a latch signal latched by changing a level when an output of the XOR circuit changes from 0 to 1.

9. The memory device of claim 8, further comprising a second external terminal configured to externally output an error detection latch signal based on the latch signal,
wherein the latch of the latch signal is reflected in latch of the error detection latch signal.

10. The memory device of claim 8, wherein when the latch signal is latched, data indicating an abnormality is written in the memory array.
